(19) United States
(12) Patent Application Publication
(10) Pub. No.: US 2012/0319138 A1
(43) Pub. Date: Dec. 20, 2012

(54) SEMICONDUCTOR LIGHT EMITTING DEVICE

(75) Inventors: Akihiro FUJIWARA, Fukuoka-ken (JP); Kimitaka YOSHIMURA, Fukuoka-ken (JP); Takashi HAKUNO, Fukuoka-ken (JP)

(73) Assignee: Kabushiki Kaisha Toshiba, Tokyo (JP)

(21) Appl. No.: 13/423,139

(22) Filed: Mar. 16, 2012

(30) Foreign Application Priority Data
Jun. 16, 2011 (JP) 2011-134427

(51) Int. Cl. H01L 33/48

(52) U.S. Cl. 257/79; 257/E33.055

(57) ABSTRACT

According to one embodiment, in a semiconductor light emitting device, a substrate includes a first surface and a second surface opposite to each other, lateral surfaces intersected with the first surface and the second surface, first regions each provided on the lateral surface, and second regions each provided on the lateral surface. Each of the first regions has a first width and a first roughness. Each of the second regions has a second width smaller than the first width and a second roughness smaller than the first roughness. The first region is provided from a position away from the first surface by a first distance. The first regions and the second regions are alternately arranged. A semiconductor laminated body is provided above the first surface of the substrate, and includes a first semiconductor layer, an active layer and a second semiconductor layer.

### CROSS REFERENCE TO RELATED APPLICATION

This application is based upon and claims the benefit of priority from the prior Japanese Patent Application No. 2011-134427, filed on Jun. 16, 2011, the entire contents of which are incorporated herein by reference.

### FIELD

Embodiments described herein relate generally to a semiconductor light emitting device.

### BACKGROUND

There have conventionally been provided nitride semiconductor light emitting devices in each of which a nitride semiconductor laminate body is formed on a C-plane sapphire substrate, and light is extracted not only from the nitride semiconductor laminate body but also from a lateral surface of the sapphire substrate.

In order to improve light extraction efficiency from a lateral surface of the sapphire substrate, the above-described nitride semiconductor light emitting device needs to have the sapphire substrate with a certain thickness and a roughened lateral surface.

The C-plane sapphire substrate, however, has no cleavage plane perpendicular to the C-plane, and is made of a material with high hardness and chemical stability. These properties make it difficult to divide the thick sapphire substrate into chips and to roughen the lateral surface of the sapphire substrate.

When a sapphire substrate is divided by point-scribing first and then breaking, the division begins at a point only approximately 10 μm deep from the surface of sapphire substrate. Accordingly, the thickness of the sapphire substrate needs to be within approximately 100 μm.

When a sapphire substrate is divided into chips by firstly performing an ablation process with a laser beam focused on a surface of the sapphire substrate and then by breaking, the division begins at a position only approximately 30 μm deep from the surface of a sapphire substrate. For this reason, the thickness of the sapphire substrate needs to be within approximately 130 μm.

After the sapphire substrate is divided into chips by breaking, each chip thus formed has lateral surfaces in a cracked state. For this reason, there is a problem that it is difficult to roughen such lateral surfaces.

### BRIEF DESCRIPTION OF THE DRAWINGS

FIGS. 1A to 1C are diagrams showing a semiconductor light emitting device according to an embodiment;

FIG. 2 is a chart showing the characteristic of the semiconductor light emitting device according to the embodiment;

FIG. 3 is a chart showing the characteristic of the semiconductor light emitting device according to the embodiment;

FIGS. 4A to 4C are cross-sectional view showing the semiconductor light emitting device in comparison with semiconductor light emitting devices of comparative examples according to the embodiment;

FIG. 5 is a chart showing the characteristic of the semiconductor light emitting device in comparison with that of the semiconductor light emitting devices of the comparative examples according to the embodiment;

FIG. 6 is a chart showing characteristic of the semiconductor light emitting device according to the embodiment;

FIG. 7 is a flow chart showing main portions of the steps of manufacturing the semiconductor light emitting device according to the embodiment;

FIGS. 8A and 8B are cross-sectional views showing main portions of the steps of manufacturing the semiconductor light emitting device in sequential order according to the embodiment;

### DETAILED DESCRIPTION

According to one embodiment, in a semiconductor light emitting device, a substrate includes a first surface, a second surface opposite to the first surface, a plurality of lateral surfaces intersected with the first surface and the second surface, a plurality of first regions each provided on the lateral surface, and a plurality of second regions each provided on the lateral surface. Each of the first regions has a first width and a first roughness. Each of the second regions has a second width smaller than the first width and a second roughness smaller than the first roughness. The first region is provided from a position away from the first surface by a first distance. The first regions and the second regions are alternately arranged. A semiconductor laminated body is provided above the first surface of the substrate, and includes a first semiconductor layer of a first conductivity type, an active layer, and a second semiconductor layer of a second conductivity type which are stacked one upon another in this order.

Hereinafter, embodiments will be described with reference to the drawings. In the drawings, same reference characters denote the same or similar portions.

### Embodiment

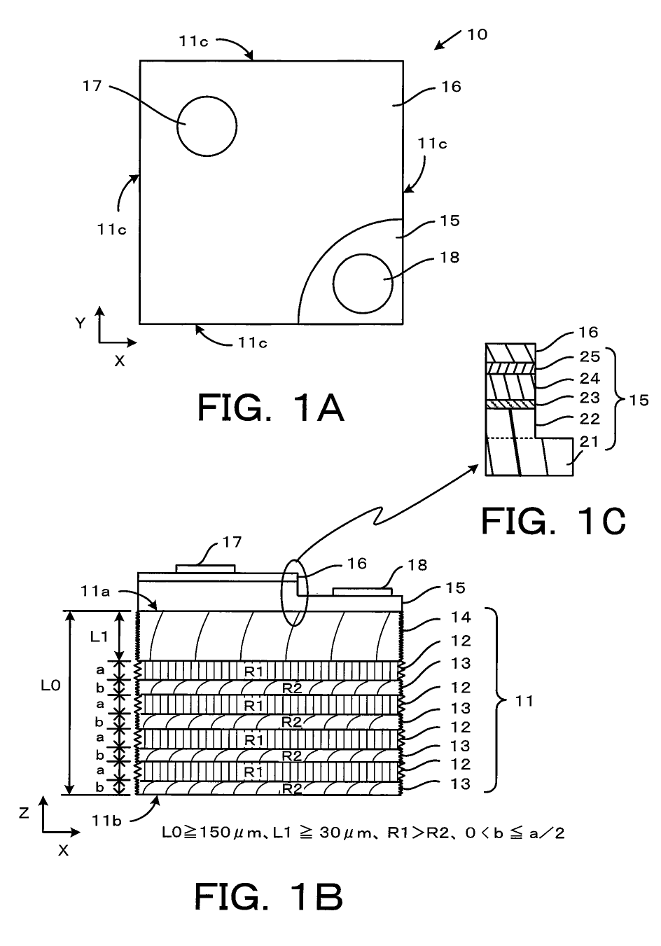

A semiconductor light emitting device of an embodiment will be described with reference to FIGS. 1A to 1C. The semiconductor light emitting device of the embodiment is a nitride semiconductor light emitting device. FIGS. 1A to 1C are diagrams showing the nitride semiconductor light emitting device. FIG. 1A is a top plan view, FIG. 1B is a lateral view, and FIG. 1C is a sectional view showing a main portion of FIG. 1B.

As shown in FIGS. 1A to 1C, a nitride semiconductor light emitting device 10 of the embodiment includes a sapphire substrate 11. The sapphire substrate 11 has a first surface 11a and a second surface 11b that are opposite to each other. The sapphire substrate 11 also has four lateral surfaces 11c each of which is intersected with the first and the second surfaces 11a, 11b. Each of the lateral surfaces is substantially perpendicular to the first and the second surfaces 11a, 11b, for example. The sapphire substrate 11 has a shape of a rectangular solid with 250 μm×250 μm square surfaces and a thickness (L0) of approximately 200 μm, for example.

A layered structure is observed in each of the lateral surfaces 11c of the sapphire substrate 11. The layered structure includes four sets of first regions 12 and second regions 13 provided alternately from a position away from the first surface 11a by a first distance L1 (e.g. approximately 30 μm) towards the second surface 11b (i.e. in the −Z direction of the drawing). Each first region 12 differs from each second region 13 in roughness and width.

In each set, the first region 12 has a first roughness R1 and a first width a. The second region 13 has a second roughness R2 that is smaller than the first roughness R1, and also has a second width b that is smaller than the first width a.

The first and second regions 12, 13 in each set are provided in a manner that the sum of the first width a and the second width b (i.e. a+b) is constant. To put it differently, the first regions 12 are repeatedly formed with a constant pitch, for example.

The second width b is larger than zero, but is not larger than half the first width a (i.e. 0<b≦a/2). The first width a is approximately 30 μm to 40 μm, for example whereas the second width b is approximately 15 μm to 20 μm, for example.

Each of the first and second regions 12, 13 extends in a direction parallel to the first surface 11a (i.e. in the X directions of the drawing) from a first end of one of the lateral surfaces 11c to a second end of the lateral surface 11c.

A nitride semiconductor laminated body 15 is provided above the first surface 11a of the sapphire substrate 11, and includes an N-type (a first conductivity type) first nitride semiconductor layer, a nitride active layer and a P-type (a second conductivity type) second nitride semiconductor layer which are stacked in this order.

The first nitride semiconductor layer includes an N-type GaN layer 21 and an N-type GaN clad layer 22, for example. The nitride active layer includes a Multiple Quantum Well (MQW) layer 23, for example. The second nitride semiconductor layer includes a P-type GaN clad layer 24 and a P-type GaN contact layer 25, for example.

A transparent conductive film 16 is provided above the nitride semiconductor laminated body 15 to spread a current and prevent an electrode material from blocking light extracted from the p-type GaN contact layer 25 side. A first electrode (a P-side electrode) 17, for example, a gold (Au) film, is provided on a portion of the transparent conductive film 16.

A second electrode (an N-side electrode) 18, for example, a laminated films including titanium (Ti)/platinum (pt)/gold (Au), is provided on the exposed N-type GaN layer 21 by removing a portion of the nitride semiconductor laminated body 15.

The first electrode 17 and the second electrode 18 are provided along the diagonal line of the sapphire substrate 11 so as to face each other.

The first region 12 and the second region 13 are formed in the following manner. Firstly, a laser beam with a wavelength to which the sapphire is translucent is focused inside the sapphire substrate, and is moved relatively to the sapphire substrate in a discrete manner, e.g. at 5-μm intervals, along a line where the sapphire substrate is to be divided. Thus, affected layers are formed inside of the sapphire substrate.

The affected layers are re-solidified sapphire regions formed by the re-solidification of sapphire that has been melted by the energy of the laser light. The strength of the affected layers is impaired by the cracks or the like that are formed in the affected layers due to the thermal strain. The size of each affected layer thus formed depends on the shape and the output power of the laser beam, and other factors. An adequate distance of the relative movement of the laser beam is longer than the diameter of the laser beam but is not longer than twice the diameter of the laser beam.

When the sapphire substrate containing the affected layers formed inside is subjected to a breaking process, the cracks formed in the affected layers stretch towards the first and the second surfaces 11a and 11b, and thereby the sapphire substrate is divided into chips.

The affected layers exposed with the division of the sapphire substrate are the first regions 12. The regions between two adjacent affected layers are the second regions 13. Accordingly, the first regions 12 includes more crystal defects than the second regions 13.

Each first region 12 forms a lateral surface having asperities and corresponding to the size of the affected layer. Each first region 12 has the first roughness R1 and the first width a.

Each second region 13, on the other hand, forms a streaky lateral surface having asperities and corresponding to the cracks. Each second region 13 has the second roughness R2 that is smaller than the first roughness R1, and also has the second width b that is smaller than the first width a. The second width b corresponds to the pitch with which the affected layers are formed.

A third region 14 is formed between the first surface 11a of the sapphire substrate 11 and the uppermost first region 12. The third region 14 forms a crack-like lateral surface, and includes terrace-like flat surfaces. Hence, the roughness of the third region 14 is smaller than the second roughness R2.

The third region 14 is formed to prevent the damage done to the nitride semiconductor laminate body 15 by the heat caused by the laser beam focused in the sapphire substrate.

The nitride semiconductor laminated body 15 is briefly described below. The N-type GaN layer 21 is a base single crystal layer on which the N-type GaN clad layer 22 to P-type GaN contact layer 25 are grown, and formed in a thickness of approximately 3 μm for example. The N-type GaN clad layer 22 is formed in a thickness of approximately 2 μm, for example.

The MQW structure 23 is formed in such a multiple quantum well structure that a GaN barrier layer with a thickness of approximately 5 nm and InGaN well layer with a thickness of approximately 2.5 nm are stacked alternately and the InGaN well layer is located at top layer, for example.

The P-type GaN clad layer 24 is formed in a thickness of approximately 100 nm, for example. The P-type GaN contact layer 25 is formed in a thickness of approximately 10 nm, for example.

A composition ratio x of In in each InGaN well layer (the InₓGa₁₋ₓN layer, 0<x<1) is set at approximately 0.1 for the purpose of making a peak light-emission wavelength equal to approximately 450 nm, for example.

The nitride semiconductor light-emitting device 10 described above is configured to improve light extraction efficiency from the lateral surfaces 11c by optimizing the thickness L0 of the sapphire substrate 11 and the roughening pattern of the lateral surfaces 11c while the reliability is secured.

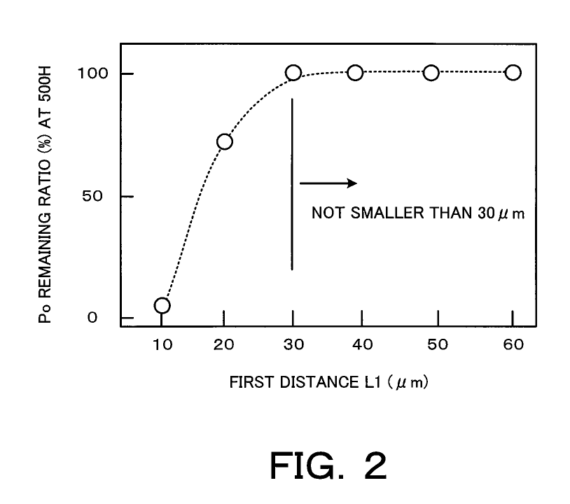

Next, characteristics of the nitride semiconductor light emitting device 10 will be described with reference to FIGS. 2 to 6. FIG. 2 is a diagram showing the relationship between the first distance L1 and the ratio of remaining initial output power of the light (hereinafter, simply referred to as the “Po-remaining ratio”) in the nitride semiconductor light emitting device 10. In FIG. 2, the horizontal axis represents the first distance L1. The vertical axis represents the Po-remaining ratio at 500 hours later. The values of Po-remaining ratio are normalized with the Po-remaining ratio obtained when the first distance L1 is 60 μm.

As shown in FIG. 2, the Po-remaining ratio is not larger than 10% when the first distance L1 is 10 μm, whereas the Po-remaining ratio is approximately 70% when the first distance L1 is 20 m. As the first distance L1 becomes shorter, the Po-remaining ratio drops drastically.

When the first distance L1 is 30 μm or more, the Po-remaining ratio is approximately 100%. Accordingly, when the laser beam is focused in the sapphire substrate with a first distance L1 of 30 μm or more, the damage on the nitride semiconductor laminate body 15 can be avoided irrespective of the thickness of the sapphire substrate 11.

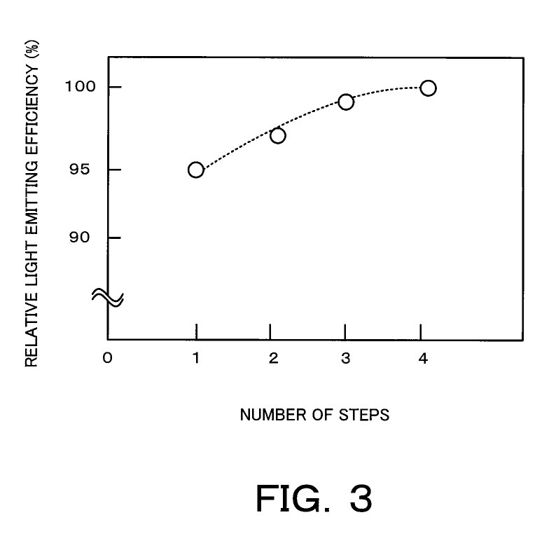

FIG. 3 is a chart showing the relationship between the light emitting efficiency and the number of sets each including one first region 12 and one second region 13. In FIG. 3, the horizontal axis represents the number of sets, and the vertical axis represents the light emitting efficiency. The values of the light emitting efficiency are normalized with the light emitting efficiency of a case where the number of sets is four.

As shown in FIG. 3, the light emitting efficiency is improved as the number of sets becomes larger, and the light emitting efficiency is saturated with the number of sets that is four or more. As the number of sets becomes larger, the roughening rate of the lateral surface 11c of the sapphire substrate 11 becomes larger. Hence, the light extraction efficiency from the lateral surface 11c can be improved and thus the light emitting efficiency can also be improved.

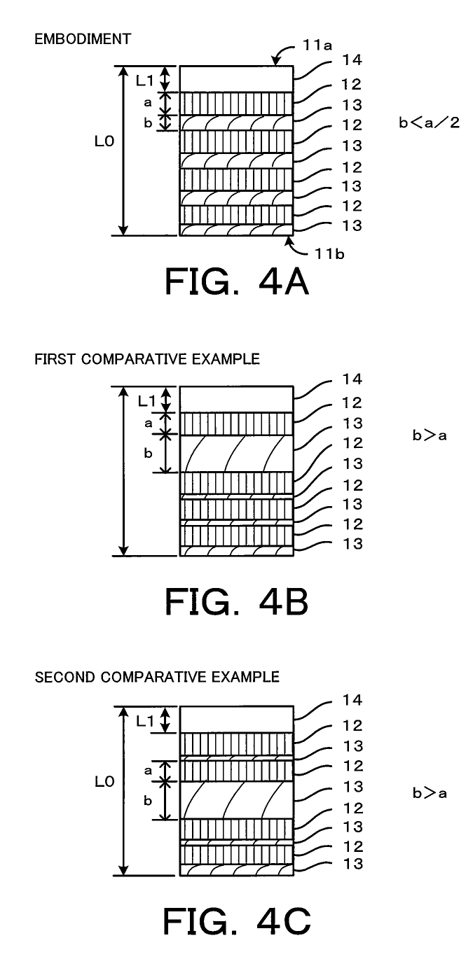

FIGS. 4A to 4C are diagrams showing various patterns in which the first and the second regions 12, 13 are laid out. FIG. 4A is a diagram showing the pattern of the embodiment, FIG. 4B is a diagram showing the pattern of a first comparative example, and FIG. 4C is a diagram showing the pattern of a second comparative example.

The pattern of the first comparative example and the pattern of the second comparative example have a second width b that does not satisfy the relationship 0<b≦a/2 in all the sets.

As shown in FIG. 4A, in the pattern of the embodiment, the first widths a of all the sets are equal to one another, and the second widths b of all the sets are equal to one another. In addition, the first width a and the second width b in the pattern of the embodiment satisfy the relationship 0<b≦a/2.

As shown in FIG. 4B, in the pattern of the first comparative example, the second width b in the first set is larger than the first width a in the same set (b>a), and the relationship 0<b≦a/2 is not satisfied.

As shown in FIG. 4C, in the pattern of the second comparative example, the second width b in the second set is larger than the first width a in the same set (b>a), and the relationship 0<b≦a/2 is not satisfied.

In short, the pattern of the embodiment is a pattern in which the lateral surface 11c is uniformly roughened. The pattern of the first comparative example is a pattern in which the upper portion is roughened to a lesser degree. The pattern of the second comparative example is a pattern in which the central portion is roughened to a lesser degree.

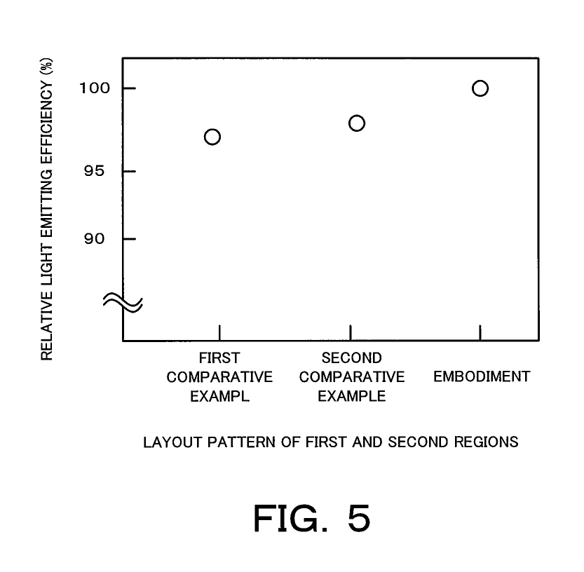

FIG. 5 is a chart showing the relationship between the light emitting efficiency and the pattern in which the first and the second regions 12, 13 are laid out. In FIG. 5, the horizontal axis represents the kinds of the patterns, and the vertical axis represents the light emitting efficiency. The values of the light emitting efficiency are normalized with the light emitting efficiency of the case of the embodiment.

As shown in FIG. 5, the light emitting efficiency obtained by the pattern of the embodiment is higher than the light emitting efficiencies obtained by patterns of the first and the second comparative examples.

A higher light emitting efficiency results from the pattern of the embodiment by the following reason. Every two adjacent affected layers are separated from each other by a distance (corresponding to the second width b) that is smaller than the width of each affected layer (corresponding to the first width a). Accordingly, the tensile stress caused by the breaking of the substrate stretches the cracks in a favorable manner, and the surfaces of the cracks are roughened to have the second roughness R2.

In contrast, in each of the patterns of the first and the second comparative examples, every two adjacent affected layers are separated from each other by a distance that is larger than the width of each affected layer. Hence, the lateral surfaces thus formed in the first and the second comparative examples are formed by the cracking that occurs at the time of breaking the substrate. Accordingly, the second roughness R2 fails to be formed in a favorable manner, and it is more difficult to roughen the lateral surface thus formed.

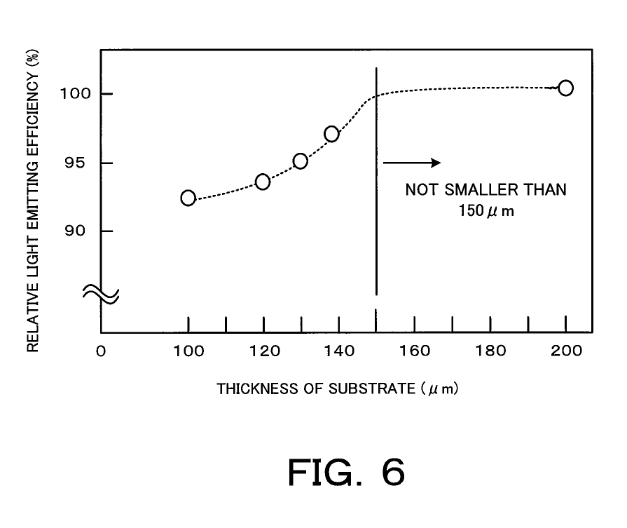

FIG. 6 is a chart showing the relationship between the thickness L0 of the sapphire substrate 11 and the light emitting efficiency. In FIG. 6, the horizontal axis represents the thickness L0 of the sapphire substrate 11. The vertical axis represents the light emitting efficiency. The values of the light emitting efficiency are normalized with the light emitting efficiency obtained when the thickness L0 of the sapphire substrate 11 is 200 μm.

As shown in FIG. 6, the light emitting efficiency tends to become higher as the thickness L0 of the sapphire substrate 11 becomes larger. The light emitting efficiency, however, is saturated when the thickness L0 of the sapphire substrate 11 is 150 μm or more. To extract the light incident on a lateral surface of the sapphire substrate 11, the sapphire substrate 11 preferably has a certain thickness.

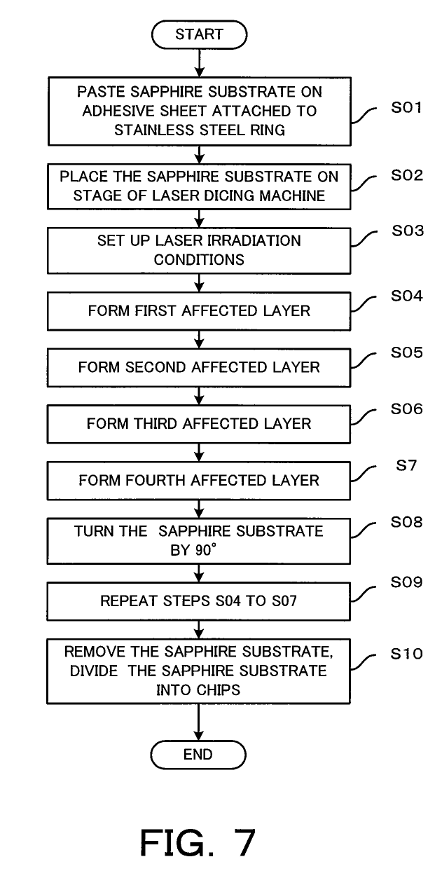

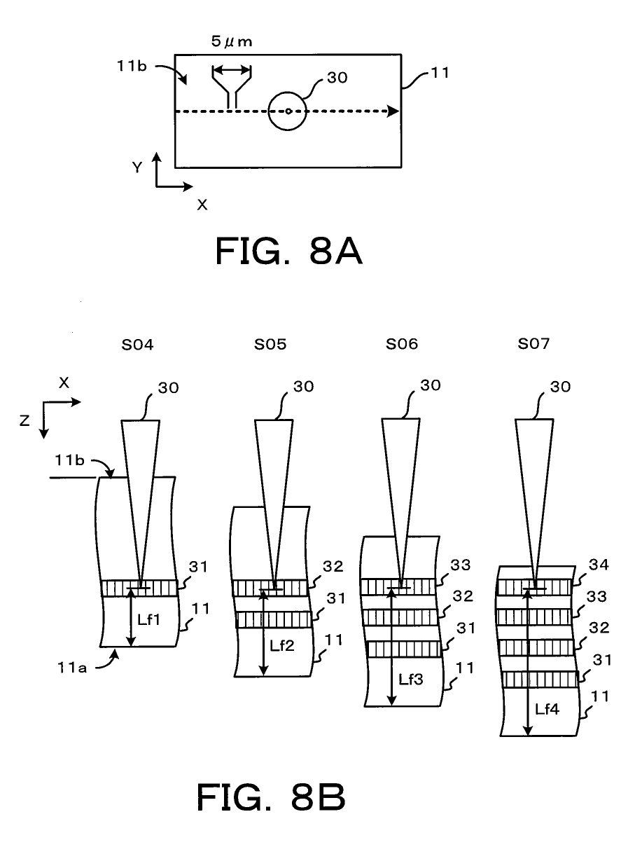

Next, a method of manufacturing the nitride semiconductor light emitting device 10 will be explained with reference to FIGS. 7 to 8B. FIG. 7 is a flowchart showing a main portion of the steps of manufacturing the nitride semiconductor light emitting device 10. FIGS. 8A and 8B are cross-sectional views showing a main portion of the steps of manufacturing the nitride semiconductor light emitting device 10.

Firstly, the nitride semiconductor laminated body 15 is formed on a sapphire substrate by a MOCVD (metal organic chemical vapor deposition) method.

The method of forming the nitride semiconductor laminated body 15 is briefly described below. As a preliminary treatment, the sapphire substrate with a C plane of a plane direction and a diameter of 150 mm is subjected to organic cleaning and acid cleaning, for example. The resultant sapphire substrate is contained in a reaction chamber of the MOCVD system.

Thereafter, the temperature of the sapphire substrate is raised to 1100° C., for example, by high-frequency heating in a normal-pressure atmosphere of a mixed gas of a nitrogen (N₂) gas and a hydrogen (H₂) gas. Thereby, the surface of the sapphire substrate is etched in gas phase, and a natural oxide film formed on the surface of the sapphire substrate is removed.

The N-type GaN layer 21 with a thickness of 3 μm is formed by using the mixed gas of the N₂ gas and the H₂ gas as a carrier gas while supplying an ammonium (NH₃) gas and a trimethyl gallium (TMG) gas, for example, as process gases, and supplying a silane (SiH₄) gas, for example, as the N-type dopant.

After the N-type GaN clad layer 22 with a thickness of 2 μm is formed in the similar manner, the temperature of the sapphire substrate is decreased to and kept at 800° C. which is lower than 1100° C., for example, while continuing supplying the NH₃ gas with the supply of the TMG gas and the SiH₄ gas stopped.

The GaN barrier layer with a thickness of 5 nm is formed by using the N₂ gas as the carrier gas while supplying the NH₃ gas, the TMG gas, for example, as the process gases. After that, the InGaN well layer with a thickness of 2.5 nm, in which the In composition ratio is 0.1, is formed by further supplying a trimethyl indium (TMI) gas, for example, as the process gas.

The forming of the GaN barrier layer and the forming of the InGaN well layer are alternately repeated 7 times, for example, while continuing or stopping the supply of the TMI gas. Thereby, the MQW layer 23 is obtained.

The undoped GaN cap layer with a thickness of 5 nm (not shown) is formed while continuing supplying the TMG gas and the NH₃ gas with the supply of the TMI gas stopped.

The temperature of the sapphire substrate is raised to and kept at 1030° C., for example, which is higher than 800° C., in the N₂ gas atmosphere while continuing supplying the NH₃ gas with the supply of the TMG gas stopped.

the P-type GaN clad layer 24 with a thickness of 100 nm, in which the concentration of Mg is approximately 1E20 cm⁻³, is formed by using the mixed gas of the N₂ gas and the H₂ gas as the carrier gas while supplying: the NH₃ gas, the TMG gas as the process gases; and a bis(cyclopentadienyl) magnesium (Cp2Mg) gas as the P-type dopant.

The P-type GaN contact layer 25 with a thickness of approximately 10 nm, in which the concentration of Mg is approximately 1E21 cm⁻³, is formed while supplying an increased amount of Cp2Mg.

The temperature of the sapphire substrate is lowered naturally with the supply of only the carrier gas continued while continuing supplying the NH₃ gas with the supply of the TMG gas stopped. The supplying of the NH₃ gas is continued until the temperature of the sapphire substrate reaches 500° C.

Thereby, the nitride semiconductor laminated body 15 is formed on the sapphire substrate and the P-type GaN contact layer 25 is located in the top surface.

An ITO (Indium tin oxide) film as a transparent conductive film 16 is formed on the P-type GaN contact layer 25 by a sputtering method, for example.

A portion of the transparent conductive film 16 is removed by a wet etching method using a mixed acid of nitric acid and hydrochloric acid so that a portion of the nitride semiconductor laminated body 15 is exposed.

The exposed portion of the nitride semiconductor laminated body 15 is anisotropically etching by a RIE (Reactive Ion Etching) method using a gas of chlorine system, so that a portion of the N-type GaN layer 21 is exposed.

The first electrode 17 is formed on the remaining portion of the transparent conductive film 16. The second electrode 18 is formed on the exposed portion of the N-type GaN layer 21.

The sapphire substrate thus obtained at this stage is one in which plural nitride semiconductor light emitting devices are arranged in a lattice shape.

Then, by following the procedure shown in FIG. 7, the sapphire substrate is divided into chips, and thereby individual nitride semiconductor light emitting devices are formed.

To begin with, the sapphire substrate is pasted on an adhesive sheet attached to a stainless ring with the nitride semiconductor laminate body 15 side facing the adhesive sheet (at step S01). Then, the sapphire substrate is placed on top of a stage of a laser dicing machine (at step S02).

The initial setup of the laser radiation conditions and the like is performed in the following manner, for example (at step S03). The laser to be used emits light with a wavelength of 1.06 μm. The output power of the laser is 300 mW. The pulse width of the laser light is in a range from 10 fs to 15 fs. The pulse recurrence frequency of the laser is 100 kHz. The process conditions include the feeding speed of 600 mm/s and the radiation intervals of 5 μm.

As shown in FIGS. 8A and 8B, the optical system to cast laser light 30 is made to focus on a depth Lf1, a 30-μm position from the first surface 11a, by adjusting the position in the Z direction. Then, laser light 30 is cast from the second surface 11b side of the sapphire substrate. Step scanning is performed at 5-μm intervals with a relative movement in the X directions between the optical system and the work (the sapphire substrate). Thus a first affected layer 31 is formed (at step S04).

Then in a similar manner to that described at step S04, the optical system is made to focus on a depth Lf2, an 75-μm position from the first surface 11a, and then a second affected layer 32 is formed (at step S05).

Then, the optical system is made to focus on a depth Lf3, a 120-μm position from the first surface 11a, and then a third affected layer 33 is formed (at step S06).

Then, the optical system is made to focus on a depth Lf4, a 165-μm position from the first surface 11a, and then a fourth affected layer 34 is formed (at step S07).

Then, the sapphire substrate is turned by 90° by turning the stage of the laser dicing machine (at step S08).

Then, in a similar manner to that described at steps S04 to S07, step scanning is performed at 5-μm intervals in the Y directions of the sapphire substrate, and thereby the first to fourth affected layers 31, 32, 33, 34 are formed (at step S09).

Then, the sapphire substrate is removed from the stainless ring, and then the sapphire substrate is divided into chips by breaking the sapphire substrate. Thus the nitride semiconductor light emitting devices 10 are obtained.

Note that after step S07, the processes performed at steps S04 to S07 are repeated by shifting the sapphire substrate in the Y directions. Every time the above-mentioned processes are repeated, the sapphire substrate is shifted over a distance corresponding to the size of each chip, e.g. 250 μm. Likewise, after step S09, the process performed at step S09 is repeated by shifting, in the X directions, the sapphire substrate over a distance corresponding to the size of each chip.

As has been described thus far, in the nitride semiconductor light emitting device 10 of the embodiment, the thickness L0 of the sapphire substrate 11 is made thicker. In addition, the four first regions 12 and the four second regions 13 are alternately formed from a position that is away from the first surface 11a by the first distance L1 towards the second surface 11b (the alternating structure can be observed in each lateral surface 11c). Each of the first regions 12 has the first roughness R1 and the first width a. Each of the second regions 13 has the second roughness R2 that is smaller than the first roughness R1 and also has the second width b that is smaller than the first width a.

Thereby, the thickness L0 of the sapphire substrate 11 and the roughening pattern of the lateral surfaces 11c are optimized.

Accordingly, the light extraction efficiency from the lateral surfaces 11C can be improved while the reliability can be secured. Consequently, the nitride semiconductor light emitting device that improves the light extraction efficiency from the lateral surfaces of the substrate can be obtained.

In the description given thus far, all the first regions 12 have the same first width a, whereas all the second regions 13 have the same second width b. However, similar effects to those obtained in the embodiment are obtainable as long as the first region 12 and the second region 13 included in the same set satisfy the relationship 0<b≦a/2.

In addition, the substrate used in the above-described embodiment is a sapphire substrate, but other substrates such as a SiC substrate may be used instead.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A semiconductor light emitting device comprising:
a substrate including
a first surface,
a second surface opposite to the first surface,
a plurality of lateral surfaces intersected with the first surface and the second surface,
a plurality of first regions each provided on the lateral surface, and having a first width and a first roughness, and
a plurality of second regions each provided on the lateral surface, and having a second width smaller than the first width and a second roughness smaller than the first roughness,
the first region being provided from a position away from the first surface by a first distance, the first regions and the second regions being alternately arranged; and
a semiconductor laminated body provided above the first surface of the substrate, and including a first semiconductor layer of a first conductivity type, an active layer, and a second semiconductor layer of a second conductivity type which are stacked one upon another in this order.

2. The semiconductor light emitting device of claim 1, wherein the substrate is a sapphire substrate, and the semiconductor laminated body is a nitride semiconductor laminated body.

3. The semiconductor light emitting device of claim 1, wherein a distance between the first surface and the second surface is 150 μm or more, and the first distance is 30 μm or more.

4. The semiconductor light emitting device of claim 1, wherein the second width is larger than zero, and is half the first width or less.

5. The semiconductor light emitting device of claim 1, wherein the first width is 30 μm to 40 μm, and the second width is 15 μm to 20 μm.

6. The semiconductor light emitting device of claim 1, wherein the four or more first regions and the four or more second regions are alternately formed.

7. The semiconductor light emitting device of claim 1, wherein each of the first and second regions extends in a direction parallel to the first surface from a first end of the lateral surface to a second end of the lateral surface.

8. The semiconductor light emitting device of claim 1, further comprising a transparent conductive film provided above the second semiconductor layer of the semiconductor laminated body, and having translucency to light emitted from the active layer.

9. The semiconductor light emitting device of claim 1, wherein the first and second regions are the exposed regions formed:
firstly by forming affected layers by focusing, into the substrate, a laser beam emitted from the second-surface side, and then relatively moving the laser beam in a discrete manner along a line where the substrate is to be divided; and
then by breaking the substrate.

10. The semiconductor light emitting device of claim 9, wherein the laser beam is moved relatively in a discrete manner by a distance being longer than the diameter of the laser beam, and being not longer than twice the diameter of the laser beam.

11. A semiconductor light emitting device comprising:
a sapphire substrate including
a first surface,
a second surface opposite to the first surface,
a plurality of lateral surfaces intersected with the first surface and the second surface,
a plurality of first regions each provided on the lateral surface, and having a first width and a first roughness, and
a plurality of second regions each provided on the lateral surface, and having a second width smaller than the first width and a second roughness smaller than the first roughness,
the first region being provided from a position away from the first surface by a first distance, the first regions and the second regions being alternately arranged; and
a nitride semiconductor laminated body provided above the first surface of the sapphire substrate, and including a first nitride semiconductor layer of a first conductivity type, a nitride active layer, and a second nitride semiconductor layer of a second conductivity type which are stacked one upon another in this order.

12. The semiconductor light emitting device of claim 11, wherein a distance between the first surface and the second surface is 150 μm or more, and the first distance is 30 μm or more.

13. The semiconductor light emitting device of claim 11, wherein the second width is larger than zero, and is half the first width or less.

14. The semiconductor light emitting device of claim 11, wherein the first width is 30 μm to 40 μm, and the second width is 15 μm to 20 μm.

15. The semiconductor light emitting device of claim 11, wherein the four or more first regions and the four or more second regions are alternately formed.

16. The semiconductor light emitting device of claim 11, wherein each of the first and second regions extends in a direction parallel to the first surface from a first end of the lateral surface to a second end of the lateral surface.

17. The semiconductor light emitting device of claim 11, further comprising a transparent conductive film provided above the second semiconductor layer of the semiconductor laminated body, and having translucency to light emitted from the active layer.

18. The semiconductor light emitting device of claim 11, wherein the first and second regions are the exposed regions formed:
firstly by forming affected layers by focusing, into the sapphire substrate, a laser beam emitted from the second-surface side, and then relatively moving the laser beam in a discrete manner along a line where the sapphire substrate is to be divided; and
then by breaking the sapphire substrate.

19. The semiconductor light emitting device of claim 18, wherein the laser beam is moved relatively in a discrete manner by a distance being longer than the diameter of the laser beam, and being not longer than twice the diameter of the laser beam.
